(19) United States
(12) Patent Application Publication
(10) Pub. No.: US 2013/0285704 A1
(43) Pub. Date: Oct. 31, 2013

(54) BRIDGE INTEGRATED CIRCUIT

(71) Applicant: NOVATEK MICROELECTRONICS CORP., Hsinchu (TW)

(72) Inventor: Chiu-Huang Huang, Hsinchu County (TW)

(73) Assignee: NOVATEK MICROELECTRONICS CORP., Hsinchu (TW)

(21) Appl. No.: 13/678,167

(22) Filed: Nov. 15, 2012

(30) Foreign Application Priority Data
Apr. 25, 2012 (TW) 101114717

(51) Int. Cl. H03K 17/30

(52) U.S. Cl. CPC H03K 17/302
USPC 327/77

(57) ABSTRACT

A bridge integrated circuit adapted for being coupled between a gate driver and a tester is provided. The bridge integrated circuit comprises a plurality of first detection units and a logic unit. Each first detection unit determines whether a corresponding gate driving signal satisfies a first standard according to one of the gate driving signals provided by the gate driver and accordingly generates a first detection signal according to the determination result. The logic unit is coupled to the first detection units and generates a test result signal in response to the first detection signal provided by each first detection unit. The test result signal is adapted for the tester.

This application claims the benefit of Taiwan application Serial No. 101114717, filed Apr. 25, 2012, the subject matter of which is incorporated herein by reference.

### TECHNICAL FIELD

The disclosure relates in general to a bridge integrated circuit, and more particularly to a bridge integrated circuit between a gate driver and a tester.

### BACKGROUND

In the modern society where science and technology are continually renewed and provided, liquid crystal display has been widely used in various electronic products, such as TV, mobile phone, digital personal assistant (PAD), multimedia player and satellite navigation system. In general, liquid crystal display uses gate driver(s) to provide gate driving signals for sequentially driving the display row pixels of a display and writing corresponding data thereto.

Along with the advance and development in technology, the dimension and resolution of liquid crystal display are increased. As a result, the number of I/O pins of the gate driver increases and thus the back-end machine for testing the gate driver also needs to be upgraded. Thus, the back-end cost for testing gate drivers increases, and the test capacity becomes insufficient.

### SUMMARY OF THE DISCLOSURE

The disclosure is directed to a bridge integrated circuit adapted for being coupled between at least one gate driver and a tester. The bridge integrated circuit may comprise one or more detection units. The detection unit determines whether one of output signals from the at least one gate driver under test satisfies a standard and generates a first detection signal according to the determination result. The output signals may be a gate driving signal or a start pulse output signal, or both. The bridge integrated circuit may comprise a logic unit. The logic unit generates and provides a test result signal to the tester in response to the first detection signal provided by the detection unit. Thus, a pre-test operation is performed on the output signal(s) provided by the gate driver under test by detection units for providing the test result signal to the tester.

According to one embodiment of the present disclosure, a bridge integrated circuit adapted for being coupled between a gate driver under test and a tester is provided. The bridge integrated circuit comprises a plurality of first detection units and a logic unit. Each first detection unit determines whether a corresponding gate driving signal satisfies a first standard according to one of gate driving signals provided by one of the at least one gate driver and accordingly generates a first detection signal according to the determination result. The logic unit is coupled to the first detection units and generates a test result signal in response to the first detection signal provided by each first detection unit. The test result signal is adapted for the tester.

According to another embodiment of the present disclosure, a bridge integrated circuit adapted for being coupled between at least one gate driver under test and a tester is provided. The bridge integrated circuit comprises: a plurality of first detection units, a second detection unit, a logic unit, and a decoder. Each first detection unit determines whether a corresponding gate driving signal satisfies a first standard according to the corresponding one of a plurality of gate driving signals provided by one of the at least one gate driver and accordingly generates a first detection signal according to the determination result. The second detection unit receives and determines whether a start pulse output signal provided by one of the at least one gate driver satisfies a second standard and accordingly generates a second detection signal according to the determination result. The logic unit is coupled to the first detection units and generates a test result signal in response to the first detection signal provided by each first detection unit and the second detection signal. The decoder generates a plurality of channel enable signals respectively enabling or disabling the first detection units.

According to an alternate embodiment of the present disclosure, a bridge integrated circuit adapted for being coupled between at least one gate driver under test and a tester is provided. The bridge integrated circuit comprises: one or more detection units, and a logic unit. Each detection unit determines whether a corresponding output signals satisfies a standard according to a corresponding one of the one or more output signals provided by at least one of the at least one gate driver and generates a detection signal according to the determination result. The logic unit is coupled to the one or more detection units and generates a test result signal in response to the detection signal provided by each of the one or more detection units.

In the following detailed description, for purposes of explanation, numerous specific details are set forth in order to provide a thorough understanding of the disclosed embodiments. It will be apparent, however, that one or more embodiments may be practiced without these specific details.

In other instances, well-known structures and devices are schematically shown in order to simplify the drawing.

### BRIEF DESCRIPTION OF THE DRAWINGS

FIG. 1 shows a block diagram of a testing system according to an embodiment of the disclosure;

FIG. 2 shows signal timing diagrams of a testing system of FIG. 1;

FIG. 3 shows a detailed block diagram of a bridge integrated circuit of FIG. 1;

FIG. 4 shows a detailed block diagram of a test unit of FIG. 3;

FIG. 5 shows a detailed block diagram of a multiplexer of FIG. 4;

FIG. 6 shows another block diagram of a testing system according to an embodiment of the disclosure;

FIG. 7 shows a detailed block diagram of a bridge integrated circuit of FIG. 6 according to an embodiment of the disclosure;

FIG. 8 shows a detailed block diagram of a second detection unit of

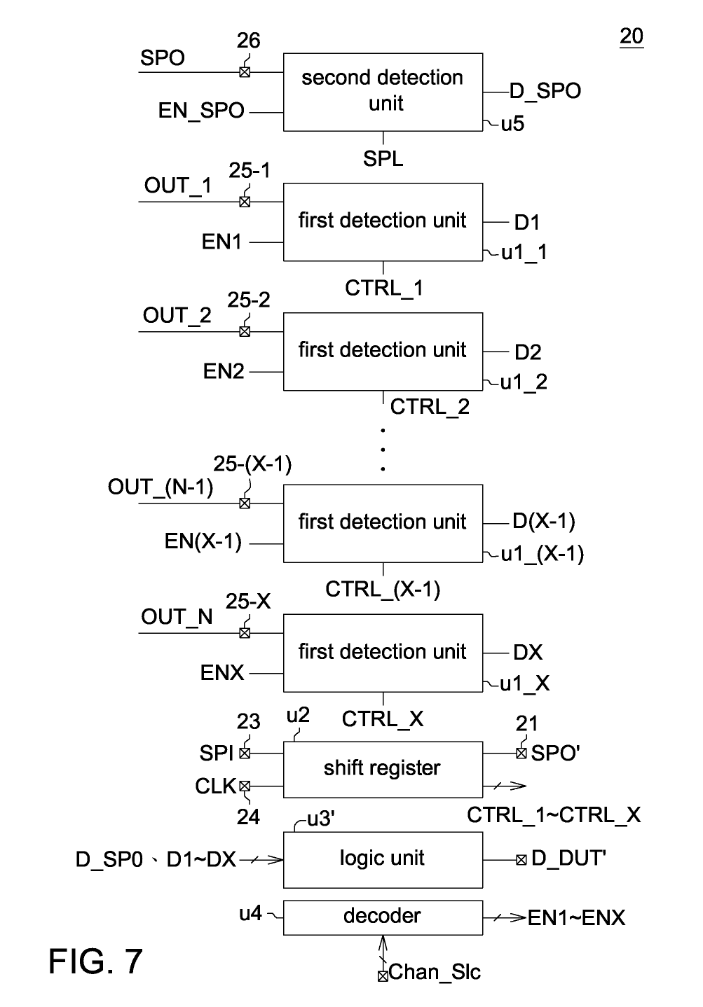

FIG. 7 according to an embodiment of the disclosure;

FIG. 9 shows an alternate block diagram of a testing system according to an embodiment of the disclosure.

### DETAILED DESCRIPTION OF THE DISCLOSURE

In the following description and claims, the term “coupling” refers to directly connection or indirectly connection. For example, “a first device is coupled to a second device” would be referred as “the first device is directly connected to the second device” or “the first device is indirectly connected to the second device via other devices or connection means”.

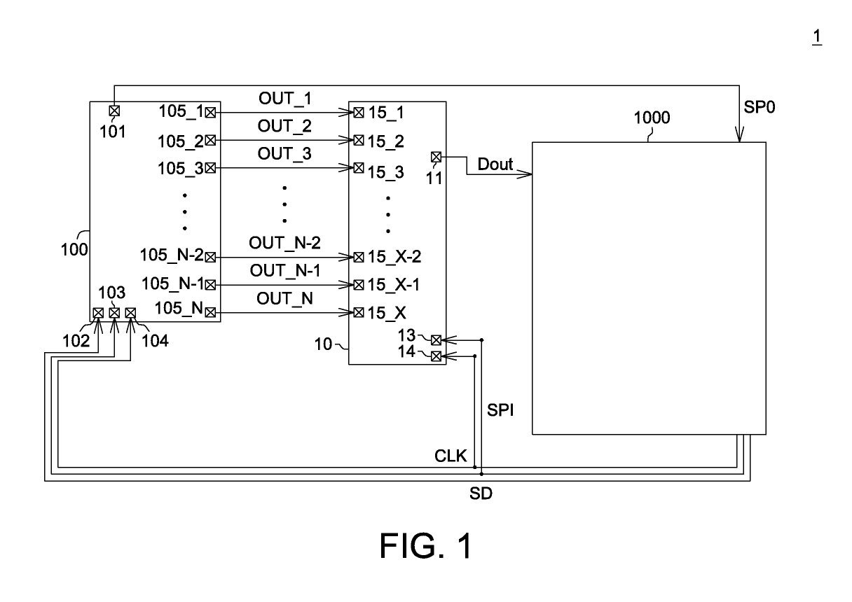

Referring to FIG. 1, a block diagram of a testing system according to an embodiment of the disclosure. The testing system 1 comprises a bridge integrated circuit 10 between a gate driver 100 and a tester 1000. The tester 1000 may for example, but not limited to, provide a start pulse input signal SPI, a pulse signal CLK and a shift direction signal SD for driving the gate driver 100 and testing gate driving signals provided by the gate driver 100.

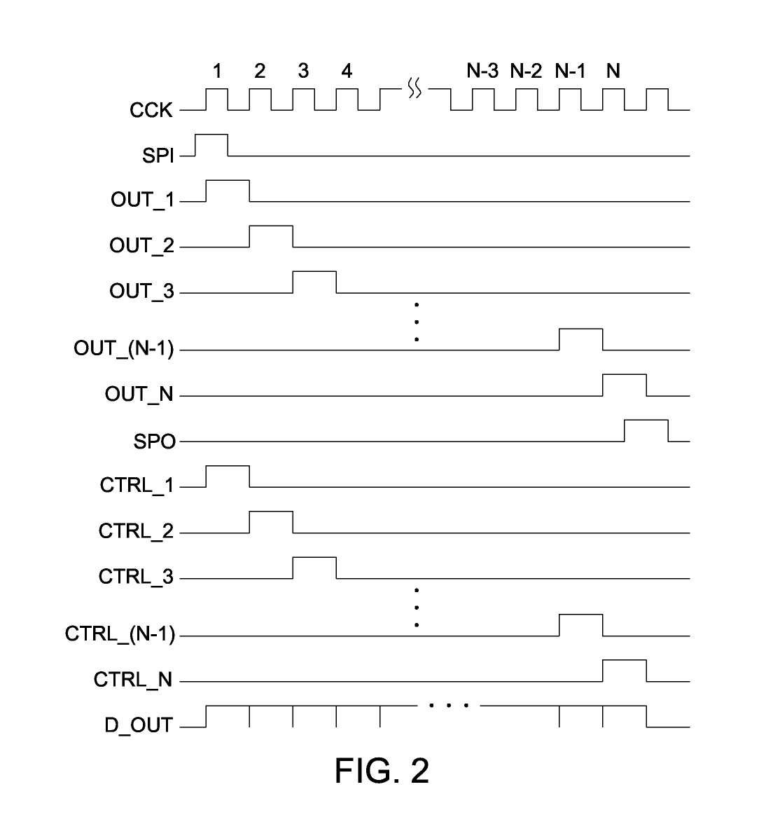

The gate driver under test 100 may comprise a shift direction pin 102, a start pulse input pin 103, a start pulse output pin 101, a clock pin 104 and N output pins 105_1, 105_2, . . . , 105_N, wherein N is a natural number greater than 1. The gate driver under test 100 receives the shift direction signal SD, the start pulse input signal SPI and the pulse signal CLK provided by the tester 1000 via the shift direction pin 102, the start pulse input pins 103 and the clock pin 104 respectively, and accordingly outputs N gate driving signals OUT_1, OUT_2, . . . , OUT_N via the N output pins 105_1˜105_N respectively. The gate driver 100 further outputs the start pulse output signal SPO via the start pulse output pin 101. For example, signal waveforms of the tester 1000 and the gate driver 100 are shown in FIG. 2.

The bridge integrated circuit 10 comprises a start pulse input signal pin 13, a test result signal pin 11, a clock pin 14 and X input pins 15_1, 15_2, . . . , 15_X, wherein X is a natural number greater than 1. The clock pin 14 and the start pulse input signal pin 13 receive the pulse signal CLK and the start pulse input signal SPI respectively. For example, X is equal to N, and the input pins 15_1˜15_X respectively receive the gate driving signals OUT_1˜OUT_N outputted by the gate driver 100. The bridge integrated circuit 10 performs a pre-test operation on the gate driving signals OUT_1˜OUT_N, and accordingly provides a test result signal D_OUT to the tester 1000.

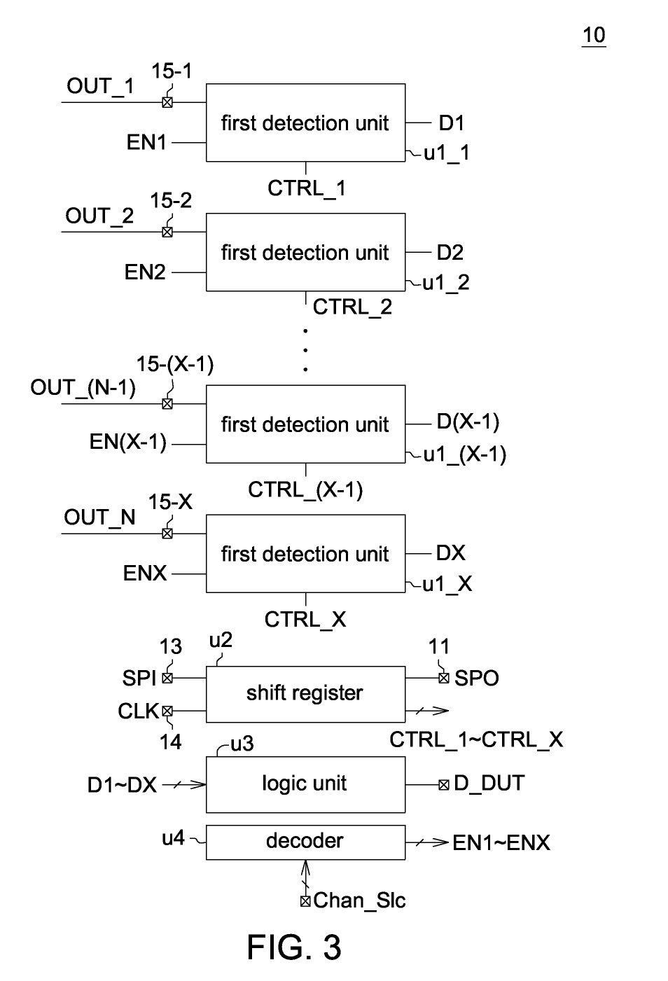

Referring to FIG. 3, a detailed block diagram of a bridge integrated circuit of FIG. 1 is shown. For example, the bridge integrated circuit 10 comprises first detection units u1_1, u1_2, . . . , u1_X, a shift register u2 and a logic unit u3. In response to the start pulse input signal SPI, the shift register u2 performs a shift operation on the pulse signal CLK to generate control signals CTRL_1, CTRL_2, . . . , CTRL_X for controlling the first detection units u1_1˜u1_X. For example, the shift register u2 performs an operation substantially the same with that performed by the gate driver 100 to generate control signals CTRL_1˜CTRL_X substantially the same with the gate driving signals OUT_1˜OUT_N according to the start pulse input signal SPI and the pulse signal CLK. The waveforms of the control signals CTRL_1˜CTRL_X are shown in FIG. 2.

Each of the first detection units u1_1˜u1_X determines whether a corresponding one of the gate driving signals OUT_1˜OUT_N satisfies a first standard according to a corresponding one of the gate driving signals OUT_1˜OUT_N provided by the gate driver 100, and accordingly generates first detection signals D1, D2, . . . , DX according to the determination result. Each of the first detection units u1_1˜u1_X determines whether the gate driving signals OUT_1˜OUT_N satisfies the first standard by determining whether the level of the corresponding one of the gate driving signals OUT_{—} 1˜OUT_{—} N s is substantially higher than or equal to a scan enable level REF_1 in an enable scan period and whether the level of the corresponding one of the gate driving signals OUT_1˜OUT_N is substantially lower than or equal to a scan disable level REF_2 in a disable non-scan period. For example, the logic unit u3 performs an AND operation on the first detection signals D1˜DX and accordingly generates the test result signal D_OUT.

The tester 1000 determines whether the operation of the gate driver 100 is normal according to the first detection signal D_OUT and the start pulse output signal SPO provided by the gate driver 100.

To summarize, through the pre-test operation performed by the bridge integrated circuit 10, the number of signals that need to be detected by the tester 1000 is reduced to 2 (the test result signal D_OUT and the start pulse output signal SPO) from N+1 (N gate driving signals OUT_1˜OUT_N and the start pulse output signal SPO) for effectively reducing the number of pins required by the tester 1000 and cost for testing the gate driver 100.

The circuit structure and operations of the bridge integrated circuit 10 are further elaborated below.

The first detection units u1_1˜u1_X has substantially the same circuit structure and operations. The operations of the first detection units u1_1˜u1_X are exemplified by the first detection unit u1_1.

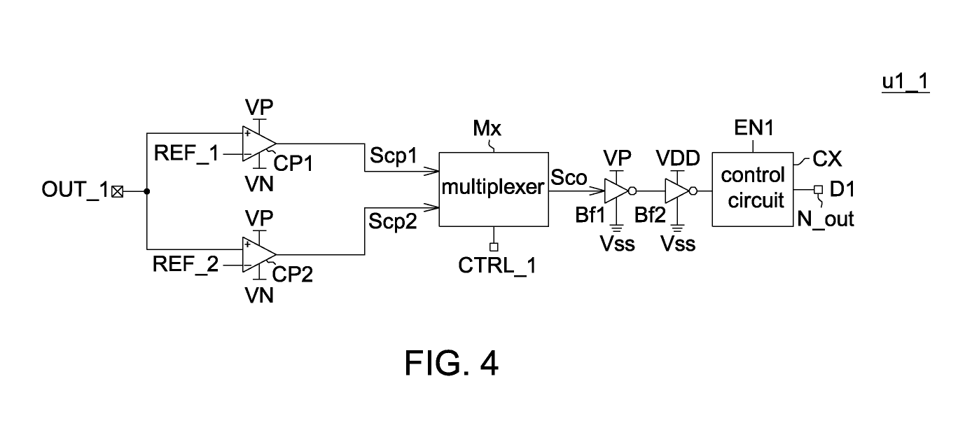

Referring to FIG. 4, a detailed block diagram of the test unit u1_1 of FIG. 3 is shown. The first detection unit u1_1 comprises first and second comparison circuits CP1 and CP2, a multiplexer Mx and two output buffers BF1 and BF2. The first comparison circuit CP1 compares the gate driving signal OUT_1 and the scan enable level REF_1, and provides a comparison signal Scp1 according to the comparison result. When the level of the gate driving signal OUT_1 is higher than the scan enable level REF_1, the comparison signal Scp1 such as is in a high signal level. When the level of the gate driving signal OUT_1 is lower than the scan enable level REF_1, the comparison signal Scp1 such as is in a low signal level.

The second comparison circuit CP2 compares the gate driving signal OUT_1 to the scan disable level REF_2, and provides a comparison signal Scp2 according to the comparison result. When the level of the gate driving signal OUT_1 is higher than the scan disable level REF_2, the comparison signal Scp2 such as is in a high signal level. When the level of the gate driving signal OUT_1 is lower than the scan disable level REF_2, the comparison signal Scp2 such as is in a low signal level.

The multiplexer Mx, in response to the control signal CTRL_1 among the control signals CTRL_1˜CTRL_X, outputs the comparison signal Scp1 as a selection output signals Sco in an enable period of the gate driving signal OUT_1, and outputs the comparison signal Scp2 as a selection output signals Sco in a disable period of the gate driving signal OUT_1. The selection output signals Sco is coupled to a detection output end N_OUT of the first detection unit u1_1. The output buffers BF1 and BF2 are between the multiplexer Mx and the detection output end N_OUT, and generate the first detection signal D1 according to the selection output signals Sco.

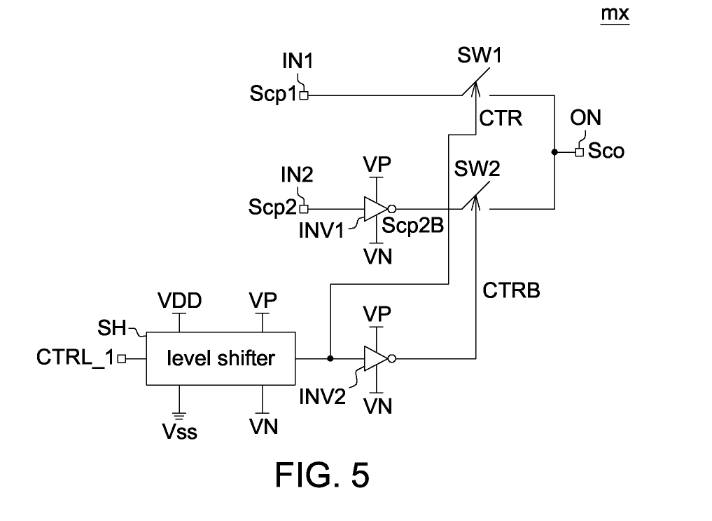

Referring to FIG. 5, a detailed block diagram of the multiplexer Mx of FIG. 4 is shown. For example, the multiplexer Mx comprises two input ends IN1 and IN2, an output end ON, two inverters INV1 and INV2, two switches SW1 and SW2 and a level shifter SH. The level shifter SH receives the control signal CTRL_1, and accordingly provides a booted control signal CTR, wherein the control signal CTRL_1 and the booted control signal CTR are enabled in the enable scan period of the gate driving signal OUT_1, and are disabled in the disable non-scan period of the gate driving signal OUT_1. For example, if the control signal CTRL_1 swings between a high reference voltage VDD and a low reference voltage VSS, the booted control signal CTR swings between a high reference voltage VP and a low reference voltage VN. The inverter INV2 receives the booted control signal CTR, and provides an inverted booted control signal CTRB.

The input end IN1 receives the comparison signal Scp1, and is coupled to output end ON via the switch SW1. The switch SW1, in response to the booted control signal CTR, is enabled in the enable scan period of the gate driving signal OUT_1 to provide the comparison signal Scp1 to the output end ON, and correspondingly outputs the comparison signal Scp1 as the selection output signals Sco in the enable scan period of the gate driving signal OUT_1.

The input end IN2 receives the comparison signal Scp2, and is coupled to output end ON via the inverter INV1 and the switch SW2. The inverter INV1 provides an inverted comparison signal Scp2B according to the comparison signal Scp2. The switch SW2, in response to the inverted and booted control signal CTRB, is enabled in the disable non-scan period of the gate driving signal OUT_1 to provide an inverted comparison signal Scp2B to the output end ON, and correspondingly outputs the comparison signal Scp2 as the selection output signals Sco in the disable non-scan period of the gate driving signal OUT_1.

For example, when the gate driving signal OUT_1 satisfies the first standard, the gate driving signal OUT_1 is enabled in the enable scan period and has a level substantially higher than or equal to the scan enable level REF_1, and is disabled in the disable non-scan period and has a level substantially lower than or equal to the scan disable level REF_2. Thus, the comparison signal Scp1 and the inverted comparison signal Scp2B are enabled in the enable scan period and the disable non-scan period respectively, and the selection output signals Sco and the first detection signal D1 are enabled. In other words, when the gate driving signal OUT_1 satisfies the first standard, the first detection units u1_1 continuously provides the enabled first detection signal D1 in the enable scan period and in the disable non-scan period.

Referring to FIG. 3 again, like the operation performed by the first detection unit u1_1 disclosed in above passages, the first detection units u1_2-u1_X of the bridge integrated circuit 10 perform substantially the same operation for detecting whether the gate driving signals OUT_2-OUT_N respectively satisfy the first standard, and generate the first detection signals D2-DX. When the gate driving signals OUT_2-OUT_N satisfy the first standard, the first detection units u1_2-u1_X provide the enabled first detection signals D2-DX. In other words, when the gate driving signals OUT_1˜OUT_N all satisfy the first standard, the waveforms of the first detection signals D1˜DX show that the first detection signals D1˜DX are continuously enabled.

Once anyone of the gate driving signals OUT_1˜OUT_N does not satisfy the first standard (for example, a gate driving signal corresponds to a disable level in the corresponding enable scan period or corresponds to an enable level in a corresponding disable non-scan period), the corresponding one of the first detection signals D1˜DX corresponds to a disable level in the corresponding period.

The logic unit u3 performs an AND operation on first detection signals D1˜DX and generates the test result signal D_OUT. When all of the gate driving signals OUT_1˜OUT_N satisfy the first standard, the first detection signals D1˜DX continuously correspond to an enable level, so that the test result signal D_OUT continuously corresponds to an enable level in N enable scan periods of the gate driving signals OUT_1˜OUT_N as indicated in signal waveforms of FIG. 2. In other words, the tester 1000 correspondingly determines whether all of the gate driving signals OUT_1˜OUT_N satisfy the first standard by determining whether the test result signal D_OUT continuously corresponds to an enable level in N consecutive enable scan periods.

In an example, the bridge integrated circuit 10 further comprises a decoder u4, which decodes a channel selection signal Chan_Slc to generate channel enable signals EN1, EN2, . . . , ENX respectively used for selectively enabling or disabling the first detection units u1_1˜u1_X. Each of the first detection units u1_1˜u1_X further comprises a control circuit CX. The first detection units u1_1˜u1_X respectively control the corresponding first detection signals D1˜DX according to the corresponding channel enable signals EN1˜ENX.

In an operating example, the number of first detection units (=X) in the bridge integrated circuit 10 is substantially greater than the number of gate driving signals (=N) outputted by the gate driver 100. In other words, the bridge integrated circuit 10 uses part of the first detection units to perform pre-test operations on the gate driver 100. In the present example, the decoder u4 may decode the channel selection signal Chan_Slec into the channel enable signals EN1˜ENX so to enable N first detection units (such as first detection units u1_1˜u1_N) of the bridge integrated circuit 10 and disable the X˜N first detection units (such as first detection units u1_N+1˜u1_X). For example, the first detection signals (such as first detection signal DN+1˜DX) of the disable X˜N first detection units continuously correspond to an enable level, so that the level of the test result signal D_OUT is determined by the first detection signals (such as the first detection signals D1˜DN) generated by the enabled N first detection units.

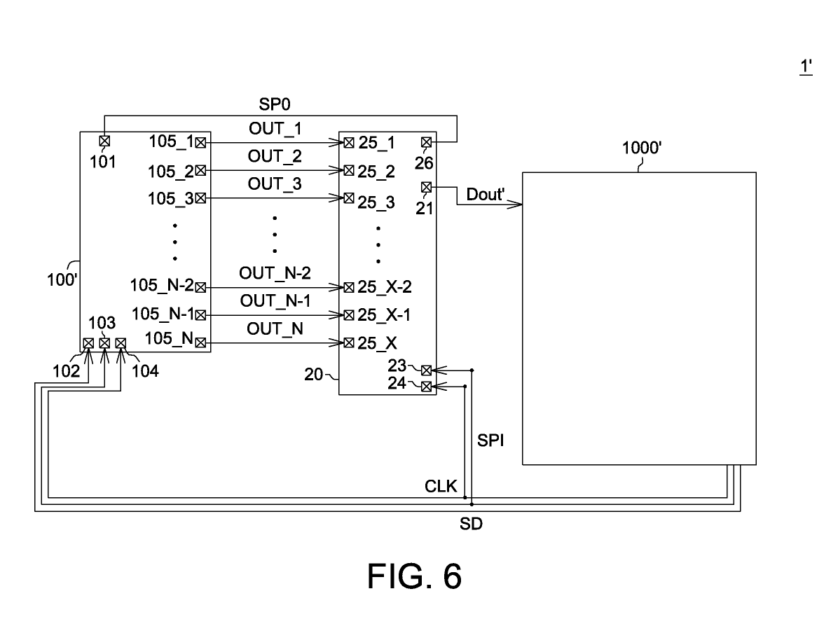

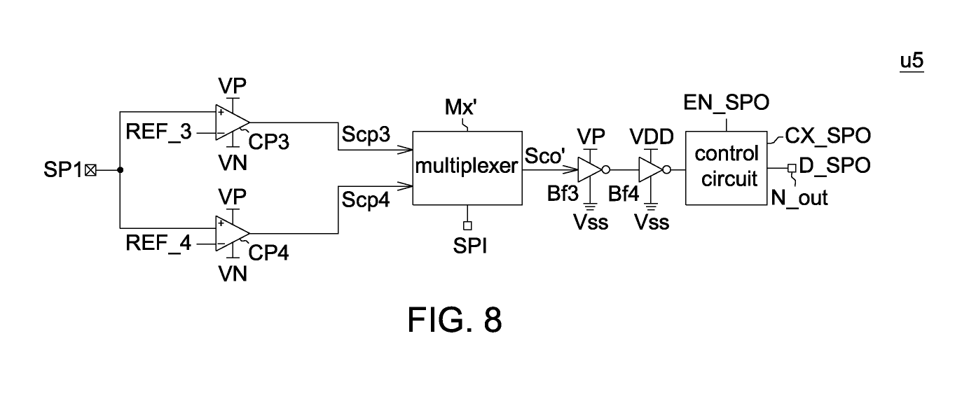

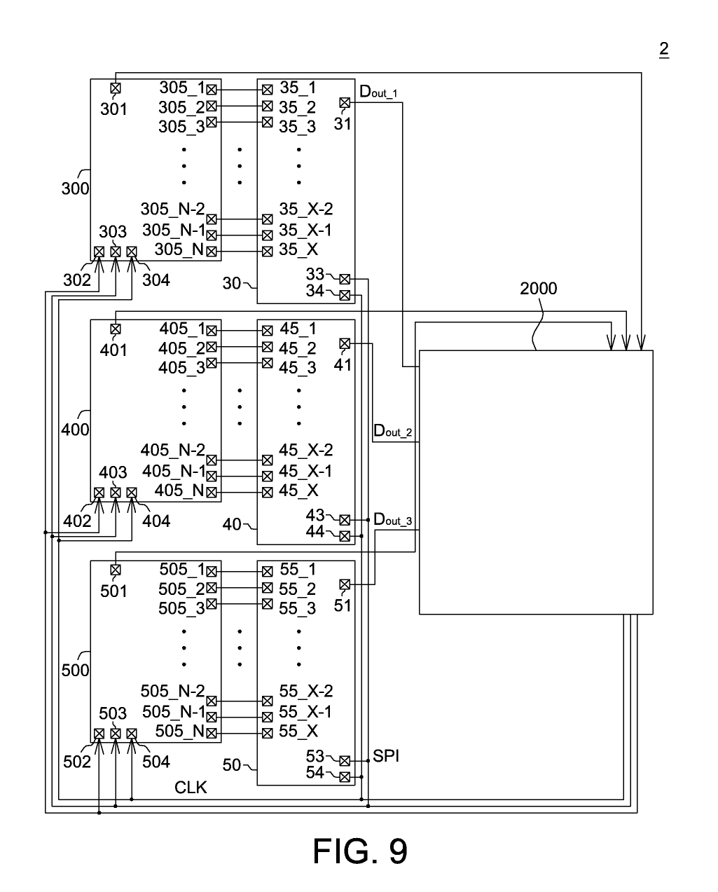

In the present embodiment, it is exemplified that the bridge integrated circuit 10 performs a pre-test operation on the gate driving signals OUT_1˜OUT_N and provides a test result signal D_OUT indicating whether the gate driving signals OUT_1˜OUT_N satisfy the first standard. However, the bridge integrated circuit 10 of the present embodiment is not limited to the above exemplification. In other example, the bridge integrated circuit 20 may concurrently perform a pre-test operation on the gate driving signals OUT_1˜OUT_N and the start pulse output signal SPO and provide a test result signal D_OUT′ indicating whether the gate driving signals OUT_1˜OUT_N satisfy the first standard and whether the start pulse output signal SPO satisfies the second standard as indicated in FIG. 6 to FIG. 8.

Furthermore, the bridge integrated circuit 20 is different from the bridge integrated circuit 10 of FIG. 3 mainly in that the bridge integrated circuit further comprises a start pulse output signal pin 26, which receives a start pulse output signal SPO provided by the gate driver 100′. In addition, the bridge integrated circuit 20 further comprises a second detection unit u5, which receives and determines whether the start pulse output signal SPO provided by the gate driver 100′ satisfies the second standard, and accordingly generates a second detection signal D_SPO according to the determination result. For example, the second detection units u5 determines whether the start pulse output signal SPO satisfies the second standard by determining whether the level of the start pulse output signal SPO is substantially higher than or equal to a start enable level in an output shift period and is substantially lower than or equal to a start disable level in a period other than the output shift period. For example, the circuit structure and operations of the second detection unit u5 are similar with those of each of the first detection units u1_1˜u1_X, and the second detection unit u5 is enabled by the enable signal EN_SPO to detect the start pulse output signal SPO and correspondingly provide the second detection signal D_SPO. Detailed descriptions are not repeated here.

The logic unit u3′ of the bridge integrated circuit 20 of the present embodiment generate a test result signal D_OUT′ based on the second detection signal D_SPO provided by the second detection units u5 and the first detection signals D1˜DX provided by the first detection units u1_1˜u1_X.

When the test result signal D_OUT′ corresponds to an enable level, it indicates that all of the gate driving signals OUT_1˜-OUT_N provided by the gate driver 100′ satisfies the first standard, and the second detection signal D_SPO provided by the gate driver 100′ satisfies the second standard. In other words, the tester 1000′ may determine whether all of the gate driving signals OUT_1˜OUT_N satisfy the first standard and whether the start pulse output signal SPO satisfies the second standard by determining whether the test result signal D_OUT′ continuously corresponds to an enable level in the enable scan period, in the disable scan period and in the output shift period of the gate driving signals OUT_1˜OUT_N.

In the present embodiment, it is exemplified that the testing system 1 employs the bridge integrated circuit 10 to drive the gate driver 100. However, the testing system 1 of the present embodiment is not limited to the above exemplification. In other examples, the testing system of the present embodiment may concurrently perform a test operation on two or more than two gate drivers as indicated in FIG. 9.

Furthermore, the testing system 2 comprises bridge integrated circuits 30, 40 and 50, which can respectively connect the gate drivers 300, 400 and 500 to the tester 2000 and perform a pre-test operation on the gate drivers 300˜500 to output test result signals Dout_1, Dout_2 and Dout_3 respectively corresponding to the gate drivers 300˜500.

A bridge integrated circuit which can be used to be coupled between a gate driver and a tester is disclosed in above embodiments of the disclosure. The bridge integrated circuit may comprise one or more detection units. The one or more detection units may comprise a plurality of first detection units, or a second detection unit, or both. As disclosed above, the first detection units respectively detect whether one of the gate signals satisfies the first standard, and the second detection unit detects whether the start pulse output signal satisfies the second standard. In other words, the detection units determine whether a corresponding output signal satisfies a standard according to one of the one or more output signals provided by the gate driver, and accordingly generates a detection signal according to the determination result. The one or more output signals comprise a plurality of gate driving signals, or a start pulse output signal, or both. The standard may comprise a first standard or second standard, or both. In addition, the bridge integrated circuit disclosed in the above embodiments further comprises a logic unit which generates and provides a test result signal to the tester in response to the detection signal provided by each detection circuit. Thus, the one or more detection circuits may perform a pre-test operation on one or more output signals and provide a test result to the tester. In comparison to conventional testing, the bridge integrated circuit of the present embodiment may perform a pre-test operation on the gate driver to effectively reduce the number of pins required by the tester and the testing cost for the gate driver.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A bridge integrated circuit adapted for being coupled between at least one gate driver under test and a tester, comprising:
a plurality of first detection units each determining whether a corresponding gate driving signal satisfies a first standard according to a corresponding one of a plurality of gate driving signals provided by one of the at least one gate driver and generating a first detection signal according to a determination result; and
a logic unit coupled to the first detection units for generating a test result signal for the tester in response to the first detection signal provided by each of the first detection units.

2. The test interface circuit according to claim 1, wherein the logic unit performs an AND operation on the first detection signals.

3. The test interface circuit according to claim 1, wherein the first standard is defined by a scan enable level, and each of the first detection units determines whether the corresponding gate driving signal is substantially higher than or equal to the scan enable level in an enable period and generates the first detection signal according to the determination result.

4. The test interface circuit according to claim 3, wherein the first standard is further defined by a scan disable level, and each of the first detection units determines whether the corresponding gate driving signal is substantially lower than or equal to the scan disable level in a disable period and generates the first detection signal according to the determination result.

5. The bridge integrated circuit according to claim 1, wherein each of the first detection units comprises:
a first comparison circuit for receiving and comparing the corresponding gate driving signal to a scan enable level, and providing a first comparison signal according to the comparison result;
a second comparison circuit for receiving and comparing the corresponding gate driving signal to a scan disable level, and providing a second comparison signal according to the comparison result;
a multiplexer for receiving the first and the second comparison signal, and selecting the first or second comparison signal as a selection output signal.

6. The bridge integrated circuit according to claim 5, wherein the multiplexer respectively outputs the first and second comparison signal as the selection output signal in an enable period and a disable period of the corresponding gate driving signal in response to a corresponding one of a plurality of control signals, and the selection output signals is coupled to a detection output end of the first detection unit.

7. The bridge integrated circuit according to claim 6, wherein each of the first detection units further comprises an output buffer between the multiplexer and the detection output end for generating the first detection signal according to the selection output signal.

8. The bridge integrated circuit according to claim 5, further comprising a shift register, which performs a shift operation on a clock signal in response to a start signal to generate a plurality of control signals respectively controlling the multiplexers of the first detection units to output the first or second selection output signal.

9. The bridge integrated circuit according to claim 1, further comprising:
a decoder for generating a plurality of channel enable signals according to a channel selection signal, wherein the channel enable signals respectively enable or disable the first detection units.

10. The bridge integrated circuit according to claim 1, further comprising a second detection unit which receives and determines whether a start pulse output signal provided by one of the at least one gate driver satisfies a second standard, and accordingly generates a second detection signal according to the determination result, wherein the second detection signal is provided to the logic unit, and the logic unit further generates the test result signal according to the second detection signal.

11. The bridge integrated circuit according to claim 10, wherein the second standard is defined by a start enable level, and the second detection units determines whether the start pulse output signal is substantially higher than or equal to the start enable level in an output shift period, and accordingly generates the second detection signal according to the determination result.

12. The bridge integrated circuit according to claim 11, wherein the second standard is defined by a start disable level, and the output second detection unit further determines whether the start pulse output signal is substantially lower than or equal to the start disable level in an output shift period, and accordingly generates the second detection signal according to the determination result.

13. A bridge integrated circuit adapted for being coupled between at least one gate driver under test and a tester, the bridge integrated circuit comprising:
a plurality of first detection units each determining whether a corresponding gate driving signal satisfies a first standard according to the corresponding one of a plurality of gate driving signals provided by one of the at least one gate driver, and generating a first detection signal;
a second detection unit for receiving and determining whether a start pulse output signal provided by one of the at least one gate driver satisfies a second standard, and accordingly generating a second detection signal;
a logic unit coupled to the first detection units and the second detection units for generating a test result signal in response to the first detection signal provided by each of the first detection units and the second detection signal; and
a decoder for generating a plurality of channel enable signals respectively enabling or disabling the first detection units.

14. The test interface circuit according to claim 13, wherein the first standard is defined by a scan enable level, and each of the first detection units determines whether the corresponding gate driving signal is substantially higher than or equal to the scan enable level in an enable period, and accordingly generates the first detection signal.

15. The test interface circuit according to claim 13, wherein the first standard is defined by a scan disable level, and each of the first detection units determines whether the corresponding gate driving signal is substantially lower than or equal to the scan disable level in a disable period, and accordingly generates the first detection signal.

16. The bridge integrated circuit according to claim 13, wherein the second standard is defined by a start enable level, and the second detection unit determines whether the start pulse output signal is substantially higher than or equal to the start enable level in an output shift period, and accordingly generates the second detection signal.

17. The bridge integrated circuit according to claim 13, wherein the second standard is defined by a start disable level, and the second detection unit further determines whether the start pulse output signal in an output shift period is substantially lower than or equal to the start disable level, and accordingly generates a second detection signal.

18. A bridge integrated circuit adapted for being coupled between at least one gate driver under test and a tester, the bridge integrated circuit comprising:
one or more detection units each determining whether a corresponding output signals satisfies a standard according to the corresponding one of one or more output signals provided by at least one of the at least one gate driver and generating a first detection signal; and
a logic unit coupled to the one or more detection units for generating a test result signal in response to the first detection signal provided by each of the one or more detection units.

19. The bridge integrated circuit according to claim 18, wherein the one or more output signals comprises a plurality of gate driving signals, and the standard comprises a standard defined by at least one of a scan enable level and a scan disable level.

20. The bridge integrated circuit according to claim 18, wherein the one or more output signals comprise a start pulse output signal, and the standard comprises a standard defined by at least one of a start enable level and a start disable level.

21. The bridge integrated circuit according to claim 18, wherein the one or more output signals comprise a plurality of gate driving signals and a start pulse output signal, the one to many detection units comprise a plurality of first detection units respectively for detecting whether one of the gate signals satisfies a first standard, and a second detection unit detects whether the start pulse output signal satisfies a second standard.
